(19) United States
(12) Patent Application Publication
(10) Pub. No.: US 2016/0216099 A1
(43) Pub. Date: Jul. 28, 2016

(54) MEASUREMENT APPARATUS AND FILM-COATING DEVICE

(71) Applicants: BOE TECHNOLOGY GROUP CO., LTD., Beijing (CN); ORDOS YUANSHENG OPTOELECTRONICS CO., LTD., Ordos, Inner Mongolia Autonomous Region (CN)

(72) Inventors: Haidong WU, Beijing (CN); Qun MA, Beijing (CN)

(73) Assignees: BOE TECHNOLOGY GROUP CO., LTD., Beijing (CN); ORDOS YUANSHENG OPTOELECTRONICS CO., LTD., Ordos, Inner Mongolia Autonomous Region (CN)

(21) Appl. No.: 14/917,050

(22) PCT Filed: Sep. 1, 2014
(86) PCT No.: PCT/CN2014/085658

§ 371 Date: Mar. 7, 2016

(30) Foreign Application Priority Data
May 13, 2014 (CN) 201410200994.1

(51) Int. Cl. G01B 7/06; C23C 14/54

(52) U.S. Cl. CPC G01B 7/066; C23C 14/54

(57) ABSTRACT

The present disclosure provides a measurement apparatus and a film-coating device. The measurement apparatus includes a first quartz-crystal oscillator sheet coated with the film during the film-coating, a second quartz-crystal oscillator sheet shielded during the film-coating so as not to be coated with the film, an excitation source generation unit configured to generate alternating current and output the alternating current to the first quartz-crystal oscillator sheet and the second quartz-crystal oscillator sheet, a first calculation module configured to calculate a frequency-variation initial value in accordance with a first response signal, a second calculation module configured to calculate a frequency-variation modified value in accordance with a second response signal, and a third calculation module configured to calculate a thickness of the film in accordance with a frequency-variation target value obtained by modifying the frequency-variation initial value with the frequency-variation modified value.

### CROSS-REFERENCE TO RELATED APPLICATION

This application claims a priority to the Chinese Patent Application No. 201410200994.1 filed on May 13, 2014, the disclosure of which is incorporated herein in its entirety by reference.

### TECHNICAL FIELD

The present disclosure relates to the field of measurement technology, and in particular to a measurement apparatus and a film-coating device.

### BACKGROUND

At present, microelectronic film, optical film, antioxidant film, giant magnetoresistance film and high temperature superconductor film have been widely applied in industry and the daily life. With respect to the films for a large scale integrated circuit, a liquid crystal panel and a liquid crystal display (LED) component, any small change in film thickness may adversely affect the performance of the component due to the increasingly improved integration degree. In addition, the properties of the film, such as light-transmission performance, conductivity and insulativity, are closely associated with its thickness.

Hence, as a very important parameter, the film thickness is directly related to the normal operation of the film, and during the production, it is necessary to acquire the film thickness.

Along with the progress of science and technology and the application of precise instrument, there are many methods for measuring the film thickness. Usually, a crystal oscillator sheet is used to measure the film thickness in real time.

However, the inventor finds that, when the crystal oscillator sheet is adopted, the measurement accuracy is insufficient due to environmental factors.

### SUMMARY

An object of the present disclosure is to provide a measurement apparatus and a film-coating device, so as to improve the accuracy when a film thickness is measured using a crystal oscillator sheet.

In one aspect, the present disclosure provides in some embodiments a measurement apparatus for measuring a thickness of a film formed on a to-be-coated module, including a first quartz-crystal oscillator sheet coated with the film during the film-coating, a second quartz-crystal oscillator sheet identical to the first quartz-crystal oscillator sheet and shielded during the film-coating so as not to be coated with the film, an excitation source generation unit configured to generate alternating current and output the alternating current to the first quartz-crystal oscillator sheet and the second quartz-crystal oscillator sheet, a first calculation module configured to calculate a frequency-variation initial value in accordance with a first response signal generated in response to the alternating current by the first quartz-crystal oscillator sheet during the film-coating, a second calculation module configured to calculate a frequency-variation modified value in accordance with a second response signal generated in response to the alternating current by the second quartz-crystal oscillator sheet during the film-coating, and a third calculation module configured to calculate a thickness of the film in accordance with a frequency-variation target value obtained by modifying the frequency-variation initial value with the frequency-variation modified value.

Alternatively, the frequency-variation target value is equal to a difference between the frequency-variation initial value and the frequency-variation modified value.

Alternatively, the measurement apparatus further includes a shielding module configured to shield the second quartz-crystal oscillator sheet during the film-coating, so as to prevent the second quartz-crystal oscillator sheet from being coated with the film.

Alternatively, there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

In another aspect, the present disclosure provides in some embodiments a film-coating device, including a film-coating machine configured to coat a to-be-coated module with a film, and a measurement apparatus including a first quartz-crystal oscillator sheet coated with the film during the film-coating, a second quartz-crystal oscillator sheet identical to the first quartz-crystal oscillator sheet and shielded during film-coating so as not to be coated with the film, an excitation source generation unit configured to generate alternating current and output the alternating current to the first quartz-crystal oscillator sheet and the second quartz-crystal oscillator sheet, a first calculation module configured to calculate a frequency-variation initial value in accordance with a first response signal generated in response to the alternating current by the first quartz-crystal oscillator sheet during the film-coating, a second calculation module configured to calculate a frequency-variation modified value in accordance with a second response signal generated in response to the alternating current by the second quartz-crystal oscillator sheet during the film-coating, and a third calculation module configured to calculate a thickness of the film in accordance with a frequency-variation target value obtained by modifying the frequency-variation initial value with the frequency-variation modified value.

Alternatively, the frequency-variation target value is equal to a difference between the frequency-variation initial value and the frequency-variation modified value.

Alternatively, the film-coating device further includes a shielding module configured to shield the second quartz-crystal oscillator sheet during the film-coating, so as to prevent the second quartz-crystal oscillator sheet from being coated with the film.

Alternatively, the first quartz-crystal oscillator sheet and the second quartz-crystal oscillator sheet are arranged in a circular manner, the shielding module is a rotatable shielding sheet with a via-hole, and the rotatable shielding sheet is rotated in such a manner as to enable the via-hole to be above different quartz-crystal oscillator sheets.

Alternatively, the film-coating device further includes a controller configured to control a thickness of the film coated by the film-coating machine in accordance with an actual value of the thickness of the film.

Alternatively, the film-coating machine includes a vacuum adsorption apparatus including an adsorption surface and configured to adsorb the to-be-coated module, and the first quartz-crystal oscillator sheet and the second quartz-crystal oscillator sheet are arranged at a level identical to the to-be-coated module.

Alternatively, there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating and calculate a mean value of all the frequency-variation median values as the frequency-variation modified value.

According to the embodiments of the present disclosure, the first quartz-crystal oscillator sheet is provided so as to obtain an initial value of the film using an existing film thickness measuring method. As described hereinabove, the frequency variation of the quartz-crystal oscillator sheet is related to both the film thickness and the environmental factors, so the film thickness calculated based on the oscillation frequency variation of the quartz-crystal oscillator sheet coated with the film is inaccurate. In this case, the second quartz-crystal oscillator sheet is further provided and shielded during the film-coating so as not to be coated with the film. The modified value may be obtained based on the oscillation frequency variation of the second quartz-crystal oscillator sheet, so as to remove an error in the oscillation frequency variation of the due to the environmental factors from the initial value of the film thickness, thereby to improve the film thickness detection accuracy.

### BRIEF DESCRIPTION OF THE DRAWINGS

FIG. 1 is a schematic view showing the situation where a plurality of quartz-crystal oscillator sheets cooperates with a shielding mechanism; and

FIG. 2 is a schematic view showing a film-coating device for a vacuum evaporation according to one embodiment of the present disclosure.

### DETAILED DESCRIPTION

According to the measurement apparatus and the film-coating device in the embodiments of the present disclosure, a quartz-crystal oscillator sheet not coated with a film is used to measure the influence on the frequency variation due to the environmental factors during the film-coating, so as to improve the measurement accuracy.

In order to facilitate the understanding of the present disclosure, the background knowledge involved therein will be described hereinafter.

When a film thickness is measured by a quartz-crystal oscillator sheet, a following approximate linearity relationship between an oscillation frequency variation of the quartz-crystal oscillator sheet and a thickness of a deposited film is used:

$$Δ f = - \frac{{f}_{Q}^{2} {ρ}_{f}}{N {ρ}_{Q}} Δ {d}_{f} .$$

where Δf is the oscillation frequency variation of the quartz-crystal oscillator sheet, Δd_{f} is the thickness of the deposited film, ρ_{f} is a density of the deposited film, ρ_{Q} is a density of the quartz-crystal oscillator sheet, f_{Q} is an inherent resonant frequency of the quartz-crystal oscillator sheet, and N is a frequency constant of the quartz-crystal oscillator sheet.

As can be seen from the above equation, when there is a small change in the thickness of the deposited film, it may be deemed that there exists approximate linearity relationship between Δf and Δd_{f}, so it is able to obtain the film thickness based on the oscillation frequency variation of the quartz-crystal oscillator sheet.

However, the oscillation frequency variation of the quartz-crystal oscillator sheet is related to both the thickness of the deposited film and an environmental factor within a film-coating cavity (e.g., temperature, vacuum degree). Hence, it is impossible to obtain the accurate film thickness using the crystal oscillator sheet.

The present disclosure provides in some embodiments a measurement apparatus for measuring a thickness of a film formed on a to-be-coated module, which includes first quartz-crystal oscillator sheet coated with the film during the film-coating, a second quartz-crystal oscillator sheet identical to the first quartz-crystal oscillator sheet and shielded during the film-coating so as not to be coated with the film, an excitation source generation unit configured to generate alternating current and output the alternating current to the first quartz-crystal oscillator sheet and the second quartz-crystal oscillator sheet, a first calculation module configured to calculate a frequency-variation initial value in accordance with a first response signal generated in response to the alternating current by the first quartz-crystal oscillator sheet during the film-coating, a second calculation module configured to calculate a frequency-variation modified value in accordance with a second response signal generated in response to the alternating current by the second quartz-crystal oscillator sheet during the film-coating, and a third calculation module configured to calculate a thickness of the film in accordance with a frequency-variation target value obtained by modifying the frequency-variation initial value with the frequency-variation modified value.

According to the embodiments of the present disclosure, the first quartz-crystal oscillator sheet is provided so as to obtain an initial value of the film using an existing film thickness measuring method. As described hereinabove, the frequency variation of the quartz-crystal oscillator sheet is related to both the film thickness and the environmental factors, so the film thickness calculated based on the oscillation frequency variation of the quartz-crystal oscillator sheet coated with the film is inaccurate. In this case, the second quartz-crystal oscillator sheet is further provided and shielded during the film-coating so as not to be coated with the film. The modified value may be obtained based on the oscillation frequency variation of the second quartz-crystal oscillator sheet, so as to remove an error in the oscillation frequency variation of the due to the environmental factors from the initial value of the film thickness, and obtain the frequency variation target value in an accurate manner, thereby to accurately calculate the film thickness in accordance with the frequency variation target value capable of accurately reflecting the change in the film thickness.

Alternatively, the frequency-variation target value is equal to a difference between the frequency-variation initial value and the frequency-variation modified value.

During the implementation, it is necessary to shield the second quartz-crystal oscillator sheet during the film-coating so as not to be coated with the film. Hence, a shielding mechanism may be provided in the measurement apparatus to shield the second quartz-crystal oscillator sheet during the film-coating, so as to prevent the second quartz-crystal oscillator sheet from being coated with the film.

Of course, the shielding mechanism may also be arranged on a film-coating machine, which will be described hereinafter.

In some embodiments of the present disclosure, there may be only one second quartz-crystal oscillator sheet. However, in order to improve the measurement accuracy, there may be a plurality of second quartz-crystal oscillator sheet. In this case, the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

The present disclosure further provides in some embodiments a film-coating device, which includes a film-coating machine configured to coat a to-be-coated module with a film, and a measurement apparatus. The measurement apparatus includes a first quartz-crystal oscillator sheet coated with the film during the film-coating, a second quartz-crystal oscillator sheet identical to the first quartz-crystal oscillator sheet and shielded during film-coating so as not to be coated with the film, an excitation source generation unit configured to generate alternating current and output the alternating current to the first quartz-crystal oscillator sheet and the second quartz-crystal oscillator sheet, a first calculation module configured to calculate a frequency-variation initial value in accordance with a first response signal generated in response to the alternating current by the first quartz-crystal oscillator sheet during the film-coating, a second calculation module configured to calculate a frequency-variation modified value in accordance with a second response signal generated in response to the alternating current by the second quartz-crystal oscillator sheet during the film-coating, and a third calculation module configured to calculate a thickness of the film in accordance with a frequency-variation target value obtained by modifying the frequency-variation initial value with the frequency-variation modified value.

Alternatively, the frequency-variation target value is equal to a difference between the frequency-variation initial value and the frequency-variation modified value.

Alternatively, the film-coating device further includes a shielding module configured to shield the second quartz-crystal oscillator sheet during the film-coating, so as to prevent the second quartz-crystal oscillator sheet from being coated with the film.

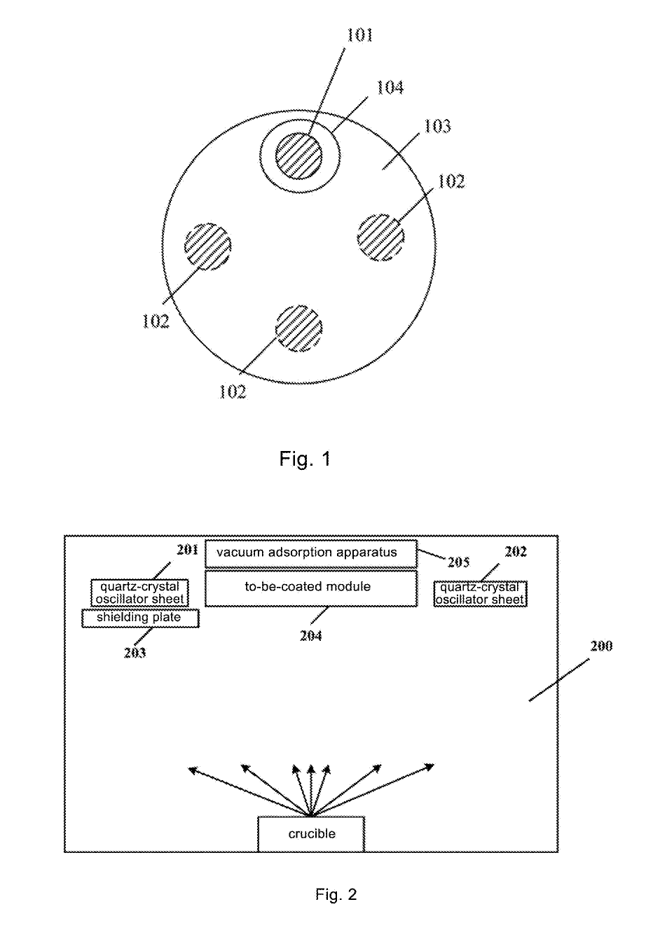

For the film-coating device, in order to improve the measurement accuracy and reduce the replacement times of the crystal oscillator sheet for measurement, as shown in FIG. 1, the first quartz-crystal oscillator sheet 101 and the second quartz-crystal oscillator sheet 102 are arranged in a circular manner, the shielding module is a rotatable shielding sheet 103 with a via-hole 104, and the rotatable shielding sheet 103 is rotated in such a manner as to enable the via-hole 104 to be above different quartz-crystal oscillator sheets.

It should be appreciated that, the so-called first quartz-crystal oscillator sheet and the second quartz-crystal oscillator sheet refer to the sheets with respect to a certain film-coating operation. As shown in FIG. 1, the first quartz-crystal oscillator sheet is located at the top, and the other quartz-crystal oscillator sheets are the second quartz-crystal oscillator sheets.

When the via-hole is rotated by 90 degrees counterclockwise and the next film-coating operation is performed, the first quartz-crystal oscillator sheet is the one on the left, and the other quartz-crystal oscillator sheets are the second quartz-crystal oscillator sheets.

For the structure in FIG. 1, the quartz-crystal oscillator sheets may be replaced after at least three film-coating operations. In the first two measurement operations, there may be two or more quartz-crystal oscillator sheets for measuring the oscillation frequency variation due to the environmental factors, so it is able to improve the measurement accuracy.

During the film-coating, it is able to measure the film thickness and control the operation of the film-coating machine based on the film thickness. At this time, the film-coating device further includes a controller configured to control a thickness of the film coated by the film-coating machine in accordance with an actual value of the thickness of the film.

For example, for the vacuum evaporation process, an evaporation temperature and a material feeding speed may be controlled.

In the embodiments of the present disclosure, the quartz-crystal oscillator sheets may be arranged at any position within the film-coating cavity. However, when the quartz-crystal oscillator sheets and the to-be-coated module are arranged at different levels, the films formed on the quartz-crystal oscillator sheets and the to-be-coated module may be of different thicknesses. At this time, a modification factor needs to be provided so as to modify the film thickness.

In order to avoid a complex process and a resultant inaccurate film thickness due to an inaccurate modification factor, in some embodiments of the present disclosure, the film-coating machine includes a vacuum adsorption apparatus 205 including an adsorption surface and configured to adsorb the to-be-coated module. The quartz-crystal oscillator sheets and the to-be-coated module are arranged at the same level, i.e., the first quartz-crystal oscillator sheet and the second quartz-crystal oscillator sheet are arranged at a level identical to the to-be-coated module.

When there exists a plurality of second quartz-crystal oscillator sheets, the second calculation module is configured to calculate a frequency-variation median value of each second quartz-crystal oscillator sheet in accordance with the second response signal generated in response to the alternating electric current by each second quartz-crystal oscillator sheet during the film-coating, and calculate a mean value of all the frequency-variation median values as the frequency-variation modified value.

The present disclosure will be described in details in conjunction with a more specific example.

FIG. 2 is a schematic view showing the film-coating device for vacuum evaporation according to one embodiment of the present disclosure.

Before the coating, initial oscillation frequencies f₁ and f₂ of the quartz-crystal oscillator sheet 201 and the quartz-crystal oscillator sheet 202 are measured at first. The quartz-crystal oscillator sheet 201 is shielded by a shielding plate so as not to be coated with the film during the film-coating, while the quartz-crystal oscillator sheet 202 is exposed and a film may be formed on surfaces of the quartz-crystal oscillator sheet 202 and the to-be-coated module 204 through an evaporation gas generated by a crucible.

In order not to set the modification factor, the quartz-crystal oscillator sheet 202 and the to-be-coated module 204 are arranged at the same level.

After the coating, the oscillation frequencies f₁′ and f₂′ of the two quartz-crystal oscillator sheets may be measured, so as to obtain the equation Δf =(f₂′−f2)−(f₁′−f1). Δf′, =f₁′−f1, and it represents the oscillation frequency variation of the crystal oscillator sheet due to any change in the environmental factor. The accurate film thickness may be obtained through the following formula:

$$Δ f = - \frac{{f}_{Q}^{2} {ρ}_{f}}{N {ρ}_{Q}} Δ {d}_{f} .$$

The above are merely the preferred embodiments of the present disclosure. It should be appreciated that, a person skilled in the art may make further modifications and improvements without departing from the spirit of the present disclosure, and these modifications and improvements shall also fall within the scope of the present disclosure.

1. A measurement apparatus for measuring a thickness of a film formed on a to-be-coated module, comprising:
a first quartz-crystal oscillator sheet coated with the film during the film-coating;
a second quartz-crystal oscillator sheet identical to the first quartz-crystal oscillator sheet and shielded during the film-coating so as not to be coated with the film;
an excitation source generation unit configured to generate alternating current and output the alternating current to the first quartz-crystal oscillator sheet and the second quartz-crystal oscillator sheet;
a first calculation module configured to calculate a frequency-variation initial value in accordance with a first response signal generated in response to the alternating current by the first quartz-crystal oscillator sheet during the film-coating;
a second calculation module configured to calculate a frequency-variation modified value in accordance with a second response signal generated in response to the alternating current by the second quartz-crystal oscillator sheet during the film-coating; and
a third calculation module configured to calculate a thickness of the film in accordance with a frequency-variation target value obtained by modifying the frequency-variation initial value with the frequency-variation modified value.

2. The measurement apparatus according to claim 1, wherein the frequency-variation target value is equal to a difference between the frequency-variation initial value and the frequency-variation modified value.

3. The measurement apparatus according to claim 1, further comprising:
a shielding module configured to shield the second quartz-crystal oscillator sheet during the film-coating, so as to prevent the second quartz-crystal oscillator sheet from being coated with the film.

4. The measurement apparatus according to claim 3, wherein the first quartz-crystal oscillator sheet and the second quartz-crystal oscillator sheet are arranged in a circular manner, the shielding module is a rotatable shielding sheet with a via-hole, and the rotatable shielding sheet is rotated in such a manner as to enable the via-hole to be above different quartz-crystal oscillator sheets.

5. The measurement apparatus according to claim 1, further comprising a vacuum adsorption apparatus comprising an adsorption surface and configured to adsorb the to-be-coated module, wherein the first quartz-crystal oscillator sheet and the second quartz-crystal oscillator sheet are arranged at a level identical to the to-be-coated module.

6. The measurement apparatus according to claim 1, wherein there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

7. A film-coating device, comprising a film-coating machine configured to coat a to-be-coated module with a film, and a measurement apparatus, wherein the measurement apparatus comprises:
a first quartz-crystal oscillator sheet coated with the film during the film-coating;
a second quartz-crystal oscillator sheet identical to the first quartz-crystal oscillator sheet and shielded during film-coating so as not to be coated with the film;
an excitation source generation unit configured to generate alternating current and output the alternating current to the first quartz-crystal oscillator sheet and the second quartz-crystal oscillator sheet;
a first calculation module configured to calculate a frequency-variation initial value in accordance with a first response signal generated in response to the alternating current by the first quartz-crystal oscillator sheet during the film-coating;
a second calculation module configured to calculate a frequency-variation modified value in accordance with a second response signal generated in response to the alternating current by the second quartz-crystal oscillator sheet during the film-coating; and
a third calculation module configured to calculate a thickness of the film in accordance with a frequency-variation target value obtained by modifying the frequency-variation initial value with the frequency-variation modified value.

8. The film-coating device according to claim 7, wherein the frequency-variation target value is equal to a difference between the frequency-variation initial value and the frequency-variation modified value.

9. The film-coating device according to claim 7, further comprising:
a shielding module configured to shield the second quartz-crystal oscillator sheet during the film-coating, so as to prevent the second quartz-crystal oscillator sheet from being coated with the film.

10. The film-coating device according to claim 9, wherein the first quartz-crystal oscillator sheet and the second quartz-crystal oscillator sheet are arranged in a circular manner, the shielding module is a rotatable shielding sheet with a via-hole, and the rotatable shielding sheet is rotated in such a manner as to enable the via-hole to be above different quartz-crystal oscillator sheets.

11. The film-coating device according to claim 7, further comprising:
a controller configured to control a thickness of the film coated by the film-coating machine in accordance with an actual value of the thickness of the film.

12. The film-coating device according to claim 7, wherein the film-coating machine comprises a vacuum adsorption apparatus comprising an adsorption surface and configured to adsorb the to-be-coated module, and the first quartz-crystal oscillator sheet and the second quartz-crystal oscillator sheet are arranged at a level identical to the to-be-coated module.

13. The film-coating device according to claim 7, wherein there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

14. The measurement apparatus according to claim 2, wherein there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

15. The measurement apparatus according to claim 3, wherein there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

16. The measurement apparatus according to claim 4, wherein there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

17. The measurement apparatus according to claim 5, wherein there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

18. The film-coating device according to claim 87, wherein there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

19. The film-coating device according to claim 9, wherein there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.

20. The film-coating device according to claim 10, wherein there exists a plurality of second quartz-crystal oscillator sheets, and the second calculation module is configured to calculate a frequency-variation median value of each second quartz-crystal oscillator sheet in accordance with the second response signal generated in response to the alternating current by each second quartz-crystal oscillator sheet during the film-coating, and calculate a mean value of all the frequency-variation median values as the frequency-variation modified value.
